(19) United States
(12) Patent Application Publication
(10) Pub. No.: US 2002/0151165 A1
(43) Pub. Date: Oct. 17, 2002

(54) Advanced interconnection for integrated circuits

(76) Inventor: Henry Wei-Ming Chung, Taipei (TW)

Correspondence Address: WORKMAN NYDEGGER & SEELEY, 1000 EAGLE GATE TOWER, 60 EAST SOUTH TEMPLE, SALT LAKE CITY, UT, 84111, US

(21) Appl. No.: 09/836,661

(22) Filed: Apr. 17, 2001

(51) Int. Cl. H01L 21/4763; H01L 21/44

(52) U.S. Cl. 438/618; 438/653; 257/750

(57) ABSTRACT

An interconnection scheme employing a dual damascene configuration for coupling multi-layer interconnects is presented. The interconnection structure includes an underlying conductive region, generally comprised of a copper or copper-based alloy having a via hole formed thereupon, with a subsequent trench region formed yet thereupon. The via hole and trench regions are coated both on the horizontal and vertical facet with a barrier material which is thereafter anisotropically etched to remove the horizontal segments of the barrier layer. The horizontal segment attached to the conductive region of the underlying conductor is also removed such that the conductive layer formed within the trench and via hole regions directly contact the underlying conductive region. Such a direct interface forgoes the problems present in material dissimilarities and also provides an improved resistivity match.

### BACKGROUND OF THE INVENTION

1. The Field of the Invention

This invention relates generally to a method of forming multi-level interconnects in an integrated circuit. More specifically, this invention relates to a method for forming an improved dual damascene interconnection.

2. The Relevant Technology

An integrated circuit is typically comprised of a series of devices and components which are formed on a substrate and are further insulated from each other through the use of an isolation structure which makes possible the formation of individual circuit structures. These individual devices and components must be electrically connected in order to form higher-level functional circuits. A conventional method for manufacturing interconnects employs conductive layers deposited over the substrate having the devices and components formed thereon. A portion of the conductive layer is then etched away to form a functional wiring pattern. The wiring pattern may then be further protected using an insulation layer to avoid any undesirable connections or shorting with other conductive layers, components or devices. In order to functionally interconnect successive interconnection layers, a vertical via hole is formed through the insulation layer for electrical connection with the next lower wiring layer. This insulation layer, commonly referred to as an inter-metal dielectric (IMD) layer is used as an insulating layer between successive wiring or interconnection layers. The connection, between a first conductive interconnection layer and a second conductive interconnection layer or wiring pattern is achieved through the use of this vertical via.

One earlier method for fabricating interconnects between adjacent conductive interconnection layers employed separate stages for forming both the layer-connecting via and the routing interconnection wires. In that approach, a dielectric layer was formed over a first conductive interconnection layer with a photoresist layer deposited over the dielectric layer. Etching techniques were used to form a hole in the dielectric, this hole being called a via, and a conductive material was deposited in the via hole to form a conductive plug or via. A second conductive layer was thereafter deposited over the dielectric layer which electrically contacted the via. A follow-up patterning step or process then etched and removed excessive portions of the conductive layer resulting in a desired interconnection conductive pattern.

A more recent approach for providing interconnection between adjacent conductive layers has become known as the dual damascene process. In such a process, an insulation layer is formed over a lower layer structure in a planarizing manner. The insulation layer is etched to form horizontal trenches defining the wiring pattern as well as vertical via holes. That is to say the vertical profile assumes two distinct levels, one more superficial level defining the inner connection trenches and the second deeper level which defines the via holes which extend down to the lower inner connection level that exposes either a device region or a portion of the metal lines on the lower level. A conductive material is then deposited and fills both the horizontal trench regions and the vertically deeper via holes in a single metalization process. Any excessive metalization extending beyond the horizontal trench region is planarized with the upper isolation or insulating layer using a chemical-mechanical polishing (CMP) process, upon which additional inner connection layers may be placed.

FIG. 1 depicts a typical partially processed integrated circuit structure in accordance with a prior art dual damascene process. In FIG. 1, a substrate 100 comprising a first dielectric 101 and a conductive region 102 is depicted. A barrier layer 103 is deposited across first dielectric 101 and conductive region 102. A second dielectric 104, typically comprised of silicon oxide, and a barrier layer 106 are formed on first dielectric 101, conductive region 102 and barrier layer 103. The barrier layer 106 functions as an etch-stop in a subsequent etching step. In order to remove a portion of barrier layer 106, a photo-resist layer (not shown) is disposed upon barrier layer 106 and processed so as to allow exposure of the desired portion of barrier layer 106, aligned over conductive region 102. Processing thereafter removes a portion of barrier layer 106 depicted as aperture 107 which provides exposure to second dielectric 104, again aligned vertically over conductive region 102.

A third dielectric layer 114 is formed typically through a deposition process and covers barrier layer 106 including the previously etched aperture 107 within barrier layer 106. Using another patterning process such as through the application of a photo-resist layer and a patterning process, such as through the exposure of certain portions of the photo-resisted layer, not shown, and aperture 115 in the photo-resisted layer is generated which provides a selective exposure to a portion of third dielectric 114 which is aligned over a portion of second dielectric 104 defined by aperture 107, which in turn is aligned over at least a portion of conductive region 102.

Using an etching process, the exposed portion of third dielectric layer 114, defined by aperture 115, is removed to form trench 117 and the portion of second dielectric 104, defined by aperture 107, is removed to define a via hole 109. The trench 117 and the via hole 109, in combination, form a dual damascene structure opening 120.

It should be appreciated that via hole 109 may also be another trench and, as used herein, via hole also implies a more broad interpretation of a lower trench region.

Following the removal of the photo-resist layer defining aperture 115, a barrier layer 122, typically referred to as a diffusion barrier comprised of a metal such as TaN, separates the via metal from conductive region 102. It should be appreciated that barrier layer 122 conforms to the peripheral dimensions of trench 117 and via hole 109 including the bottom portion of via hole 109 that physically interfaces with conductive region 102. In FIG. 2, trench 117 and via hole 109 are filled with conductive layer 126 in a monolithic process which simultaneously fills via hole 109 and trench 117 to complete the dual damascene process.

It should be appreciated that there is a need for interconnects and vias to have low resistivity and low electromigration characteristics. Advancements in processing have enabled copper (Cu) to be a natural choice for the replacement of aluminum interconnects and vias. The electromigration characteristics of copper are superior to those of aluminum. Aluminum is approximately ten times more susceptible than copper to degradation and breakdown through electromigration. Additionally, the conductivity of copper is approximately twice that of aluminum enabling the same current to be carried through a copper interconnect having half the width of an aluminum interconnect.

While copper may appear to be a panacea, copper contaminates many of the materials used in IC processes and, therefore, care must be taken to keep copper from migrating. Several attempts have been proposed which provide some relief to the problem of copper diffusion into integrated circuit material. Several materials, particularly refractory metals, have been suggested for use as barriers to prevent the copper diffusion process. Heretofore, the formation of copper interconnects has required the copper lines to completely be surrounded with barrier layers such as barrier layer 122. While the utilization of a monolithic conductive layer 126 simultaneously formed within trench 117 and via hole 109 provided an advancement in interconnection architecture, a weakness in the process remains when interfacing with conductive region 102. For example, interface 126 at the bottom of via hole 109 is the most vulnerable interface with respect to electromigration. That is to say, when interconnection in integrated circuits fail, the failure sights are predominately located at bottom of via hole 109 depicted as interface 126. Such interconnection failures are primarily resultant from material discontinuity. The barrier layer 122 separates conductive layer 126 from conductive region 102 and in the presence of barrier layer 122 results in an increased resistivity.

It would be an improvement to advance the interface between conductive layer 126 and conductive region 102 so as to minimize electromigration potential. It would be a further improvement to enhance the interface between conductive layer 126 and conductive region 102 so as to lower the resistivity between conductive region 102 and conductive layer 126.

### BRIEF SUMMARY OF THE INVENTION

A connection scheme using the dual damascene process for providing interconnections for integrated circuits is presented. The present invention includes a structure and method for providing a direct physical coupling of the conductive layer resident within the trench and via hole dual damascene arrangement with the conductive region of a lower level circuit or interconnect portion. In the preferred embodiment, a substrate comprised of a conductive region and a first dielectric in a generally planar and adjacent arrangement provides the basis upon which the interconnect structure is developed. A first barrier layer is disposed upon the conductive region and the first dielectric region in a planar arrangement. A second dielectric structure is overlaid upon the first barrier layer to provide both isolation to the conductive region and to provide a substrate within which a via hole may be formed and into which conductive material may be placed to form a via interconnection with the conductive region.

A second barrier layer is overlaid upon the second dielectric layer. The second barrier layer is thereafter processed using photoresist-type processes to define an aperture through which an anisotropic process is performed to etch the second dielectric down to the conductive region. A third dielectric layer is thereafter overlaid upon the second barrier layer. The third dielectric layer provides both a dielectric insulator for adjacent interconnection conductors as well as provides a substrate in which a trench is etched to receive conductive material.

A third barrier layer is overlaid upon the third dielectric using photoresist processes, and aperture defined in the third barrier layer corresponds with the desired trench dimensions to be etched using an anisotropic etching procedure into the third dielectric.

Following the definition of the void within the third barrier layer, an anisotropic process is performed which etches in a horizontal direction consistent with the defined void or aperture present in the third barrier layer and in a vertical direction consistent with the depth of the second barrier layer which functions as an etch stop for the trench portion of the opening. Additionally, during the same etching step, a via hole is etched into second dielectric 212 having a horizontal dimension consistent with the aperture formed within the second barrier layer and a vertical dimension terminated by the presence of the conductive region.

Once the opening for both the trench and the via hole have been defined, a barrier layer is disposed upon all horizontal and vertical surfaces of the opening. Such deposition of the barrier layer within the opening further includes applying the barrier layer to the surface of the conductive region aligned with the via hole. Using an etched-back procedure, the horizontal segments of the barrier layer within the opening are removed with the vertical segments of the barrier layer remaining. It should be appreciated that it is desirable to mitigate material discontinuity between a conductive layer deposited within both the trench and via hole area as well as the conductive region. Therefore, the removal of the horizontal segment of the barrier layer resident within the opening that is located directly upon the conductive region is desirable. With only the vertical segments of the barrier layer within the opening remaining, a conductive layer is deposited within the trench and via hole in a monolithic process. Such a process provides a direct coupling of the conductive layer with the conductive region thereby removing the deleterious effects associated with material discontinuity.

These and other objects and features of the present invention will become more fully apparent from the following description and appended claims, or may be learned by the practice of the invention as set forth hereinafter.

### BRIEF DESCRIPTION OF THE DRAWINGS

In order that the manner in which the above-recited and other advantages and features of the invention are obtained, a more particular description of the invention briefly described above will be rendered by reference to specific embodiments thereof which are illustrated in the appended drawings. Understanding that these drawings depict only typical embodiments of the invention and are not therefore to be considered limiting of its scope, the invention will be described and explained with additional specificity and detail through the use of the accompanying drawings in which:

FIGS. 1 and 2 illustrate a barrier layer throughout the entire trench region, in accordance with the prior art;

FIG. 3 depicts the formation of barrier and dielectric layers in preparation of the formation of a via hole, in accordance with the interconnect of the present invention;

FIG. 4 depicts an etching step for patterning the formation of via hole, in accordance with a preferred embodiment of the present invention;

FIG. 5 depicts the formation of the trench region of the interconnect, in accordance with the present invention;

FIG. 6 depicts the anisotropic etching of the trench and via for the formation of the interconnect, in accordance with the present invention;

FIG. 7 depicts the deposition of a barrier layer within the trench, in accordance with a preferred embodiment of the present invention;

FIG. 8 depicts an anisotropic etch-back of the horizontal layers of the barrier, in accordance with the preferred embodiment of the present invention;

FIG. 9 depicts the deposition of interconnect material within the trench and via region, in accordance with the present invention; and

FIG. 10 depicts an alternate embodiment wherein a barrier layer is etched-back.

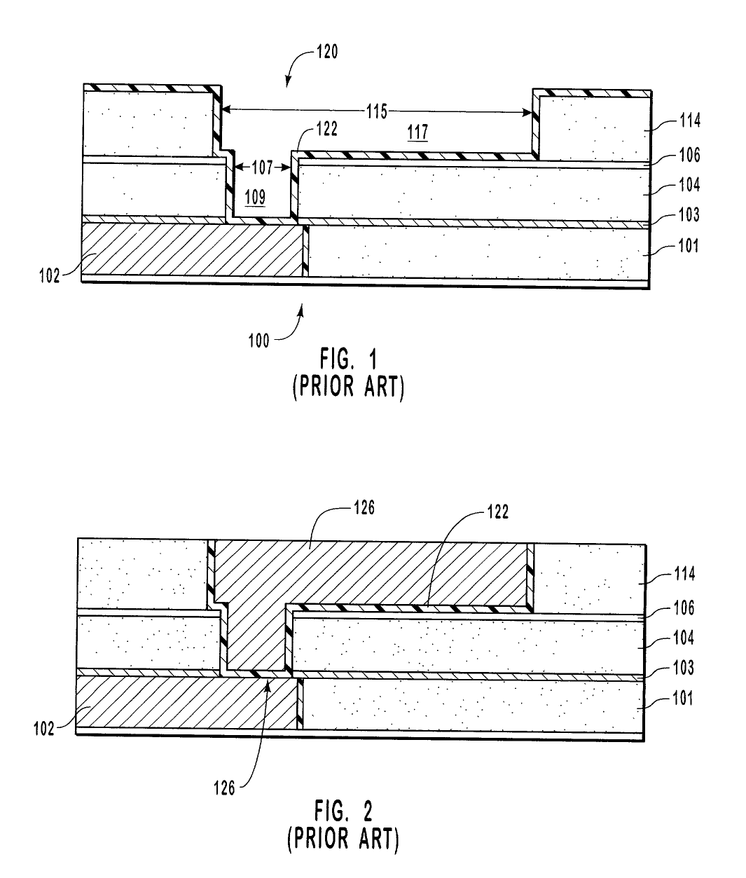

### DETAILED DESCRIPTION OF THE PREFERRED EMBODIMENTS

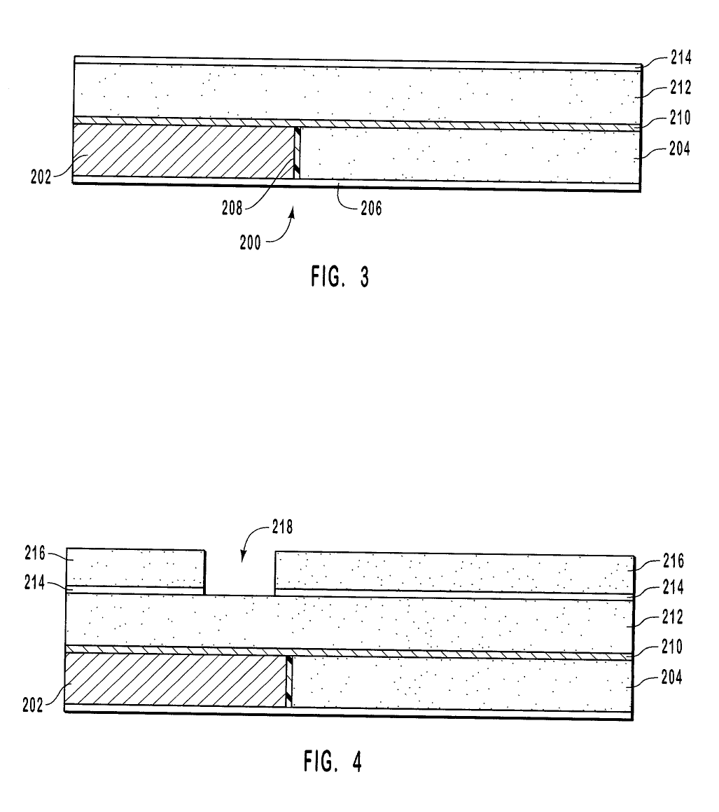

FIG. 3 depicts an integrated circuit substrate 200 having a first conductive region 202 fabricated thereupon. Conductive region 202 may comprise a metal layer defining an interconnect pattern. Substrate 200 further includes a first dielectric 204 which is formed, for example, of a silicon oxide layer formed through chemical vapor deposition (CVD) or through other processes known by those of skill in the art. Conductive region 202 and dielectric 204 may be configured atop other optional underlying structures 206. Conductive region 202 is preferably comprised of a copper (Cu) or other copper-based alloys which provide enhanced conductivity. It is however known that copper-based interconnections also suffer from out-diffusion and electromigration problems that require isolation of conductive regions using barrier techniques. Therefore, FIG. 3 depicts a barrier layer 208 for providing isolation between conductive region 202 and dielectric 204. Conductive region 202 and dielectric 204 may be further planarized in order to provide a more conducive surface for the application of additional layers.

A first barrier layer 210 is overlaid upon conductive region 202 and dielectric 204 to provide a horizontal barrier for mitigating Cu out-diffusion and electromigration of the material comprising conductive region 202. A second dielectric 212 is overlaid upon barrier layer 210 to provide an inter-metal dielectric. Dielectric 212 is typically deposited using a chemical vapor deposition process and is most generally comprised of silicon oxide. If necessary, dielectric 212 may also undergo planarization processes prior to the application of additional and successive layers and processes. Such planarization techniques are appreciated by those of skill in the art and the details of such processes are not contained herein. A second barrier layer 214 overlays dielectric 212 and is also a non-conductive barrier layer for providing Cu out-diffusion and electromigration mitigation of subsequent conductive regions.

FIG. 4 depicts a patterning structure for implementing the patterning of a via for connecting a subsequently applied conductive layer to conductive region 202. In FIG. 4, a photoresist layer 216 is applied and processed using techniques known by those of skill in the art to form an opening in the photoresist which allows for exposure of barrier layer 214 to undergo a process wherein an aperture or portion of barrier layer 214 is removed thereby exposing dielectric 212 for a subsequent etching process. It should be noted that opening 218 in barrier layer 214 is aligned so as to facilitate the formation of a via through second dielectric 212 and in vertical alignment with a portion of conductive region 202. Following the processing to form an opening or aperture 218 in second barrier layer 214, photoresist 216 is removed to accommodate subsequent processing steps.

FIG. 5 depicts formation of a trench for facilitating interconnection, in accordance with the present invention. A third dielectric layer 220 is overlaid upon second barrier layer 214 using conventional integrated circuit processing techniques known by those of skill in the art such as chemical vapor deposition or other suitable processes. Third dielectric 220 is comprised of silicon oxide and provides both isolative separation between hereafter developed conductive interconnection regions as well as providing a mold into which interconnection trenches may be formed for receiving the conductive interconnection material. A third barrier layer 222 overlays third dielectric 220 and is applied using, preferably, a deposition process. In the preferred embodiment, barrier layer 222 is comprised of a nonconductive material. Barrier layer 222 undergoes an etching process through the application of a photoresist 224 and processing of the photoresist 224 in accordance with processes known by those of skill in the art. The processing of photoresist 224 results in a mask wherein barrier layer 222 may be etched to form opening or aperture 226 within barrier layer 222. Photoresist 224 is thereafter removed leaving the desired patterning and exposure of dielectric 220.

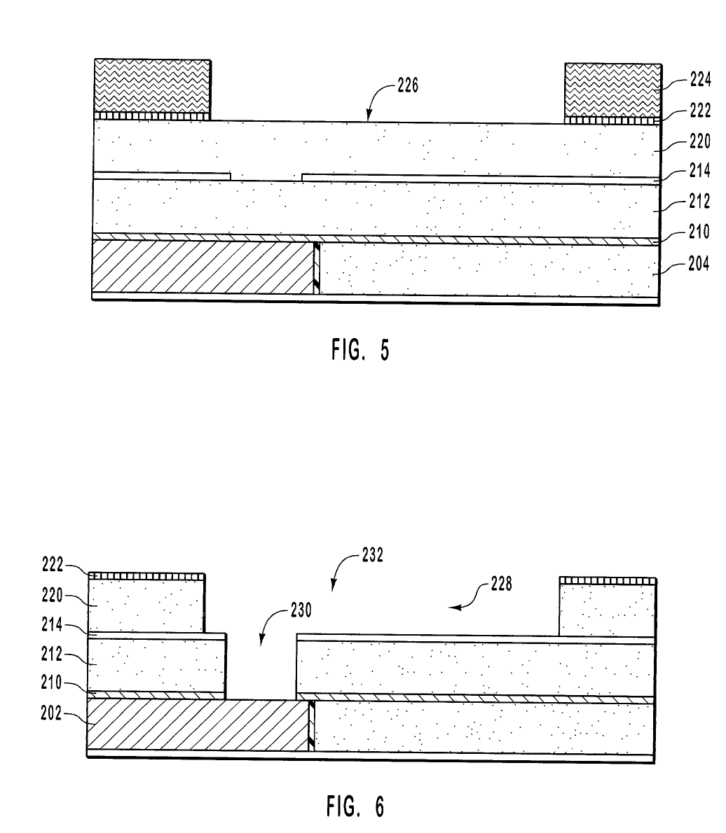

FIG. 6 depicts a cross-sectional view of an anisotropic etched dual damascene structure, in accordance with a preferred embodiment of the present invention. An anisotropic etching process with barrier layer 222 forming the aperture through which third dielectric 220 is anisotropically etched to form a trench 228 defined horizontally by barrier layer 222 and defined vertically by the presence of barrier layer 214 forming an etch stop. The anisotropic etching process further continues, preferably in the same etching process, to etch a via hole 230 through second dielectric 212 and first barrier layer 210. Via hole 230 is defined horizontally by the aperture previously etched within barrier layer 214 and further defined vertically by the existence of conductive region 202. Trench 228 and via hole 230 together combine to form an opening 232 into which a monolithic conductive interconnect will be formed with conductive region 202.

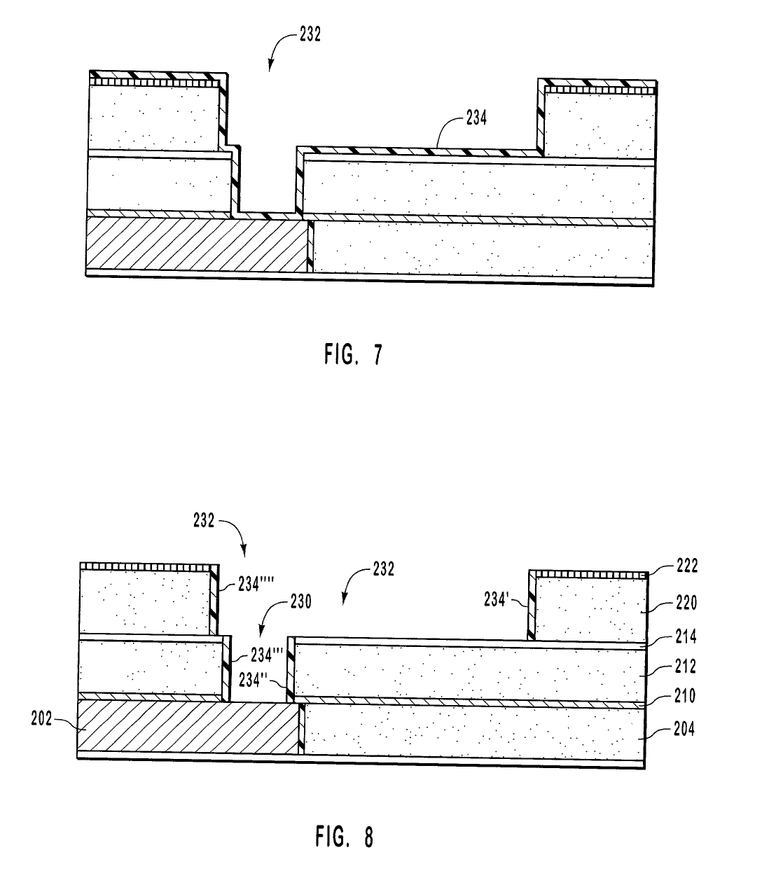

FIG. 7 is a cross-sectional view of an integrated circuit depicting a barrier layer lining the dual damascene opening of the interconnection structure, in accordance with the preferred embodiments of the present invention. As described above, conductive interconnects such as those comprised of copper or copper-based alloys, are susceptible to migration and electromigration of the copper into adjacent dielectric layers which greatly impacts the integrity of the integrated circuit. In order to mitigate such deleterious effects, a fourth barrier layer 234 is conformally applied to the surface areas of opening 232. Fourth barrier layer 234 may be comprised of, for example, titanium (Ti), titanium nitride (TiN) or tantalum (Ta) or tantalum nitride (TaN), or titanium silicon nitride (TiSiN), or other barrier compositions that minimize out-diffusion of Cu into dielectrics. It should be appreciated that fourth barrier layer 234 is applied to both the vertical and horizontal sidewalls of opening 232.

FIG. 8 is a cross-sectional diagram of the integrated circuit of the present invention after having undergone an etch-back process of the barrier layer. Fourth barrier layer 234 undergo an anisotropic etch-back process wherein the horizontal segments of barrier layer 234 undergoes an anisotropic etched-back wherein the horizontal segments of barrier layer 234 are removed with the vertical segments 234′-234″″ remaining. It should be noted that the remaining vertical segments of barrier layer 234 result in a capping of exposed dielectric layers which are susceptible to Cu out-diffusion. It should be further apparent that second barrier layer 214 provides a barrier in the horizontal direction for the conductive material that will hereinafter be placed in opening 232. It should be further apparent that the horizontal segment of barrier layer 234 located over conductive region 202 has further been removed hereby providing a direct contact between the conductive material to be placed in opening 232 with conductive region 202.

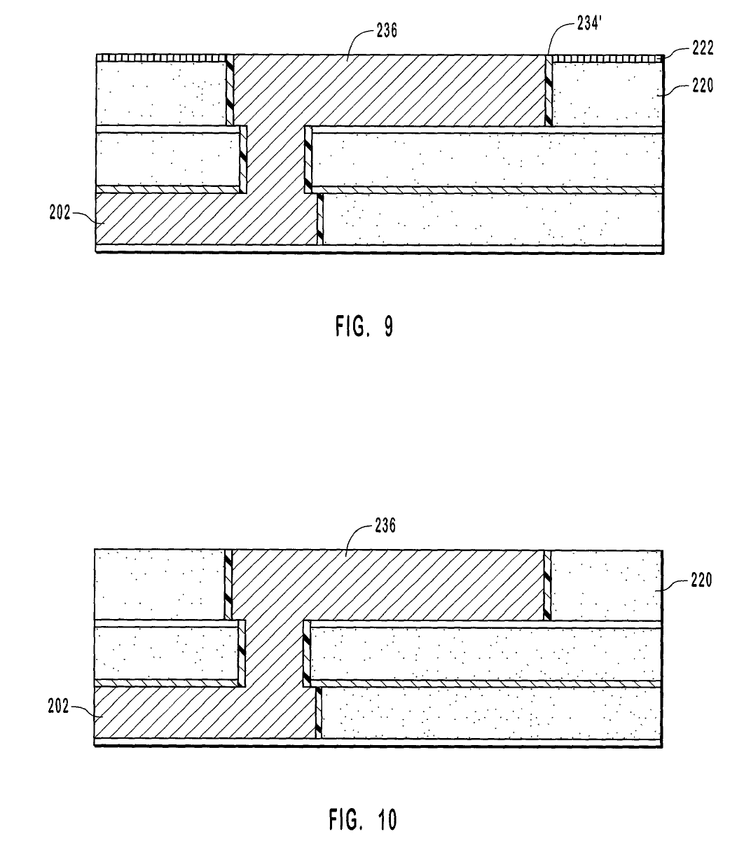

A direct physical interface of the material of conductive region 202 with the conductive layer material to be placed within opening 232 prevents failures associated with material discontinuity resulting from adjacent placement of dissimilar materials. In traditional dual damascene interconnections, the majority of interconnection failures occur at the interface located at the bottom portion of via hole 230 when the horizontal segment of barrier layer 234 remains as an obstacle between the direct connection of the material filling opening 232 with the material comprising conductive region 202. Additionally, via resistance, a critical integrated circuit device parameter, is increased when there is an intermediary material isolating conductive region 202. Therefore, the present invention provides an improvement which enables such similar conductive materials to engage in a direct physical interface. FIG. 9 is a cross-sectional diagram of a dual damascene interconnection incorporating a direct interface between the conductive layer filling the dual damascene opening with the conductive region of the underlying structure, in accordance with the preferred embodiment of the present invention. As shown, a conductive layer 236 fills both via hole 230 (FIG. 6) and trench 228 (FIG. 6) in a single monolithic process that provides a direct coupling of conductive layer 236 with conductive region 202. Conductive layer 236 is comprised of a similar, if not identical, chemical composition as conductive region 202. Preferably, conductive layer 236 and conductive region 202 are comprised of copper of copper-based metals. FIG. 9 also depicts third barrier layer 222 being comprised of a dielectric compound such that when excessive portions of conductive layer 232 extend beyond opening 232, subsequent processing or etching of conductive layer 236 does not affect barrier layer 222. Barrier layer 222, being dielectric in nature in the preferred embodiment, facilitates the electromigration barrier that is desirable to mitigate electromigration of any conductive layer overlaid upon third barrier layer 222.

FIG. 10 is a cross-sectional diagram illustrating a dual damascene interconnection for providing direct contact between a conductive layer and a conductive region without an intervening thin film or barrier, in accordance with another embodiment of the present invention. FIG. 10 depicts conductive layer 236 having the direct coupling to conductive region 202 as described in the previous figure, however, in the present embodiment, third barrier layer 222 (FIG. 8) is illustrated as being removed since it was comprised of a conductive material. During the processing of the horizontal segments of barrier layer 234 and during any etching or polishing associated with any excessive profile of conductive layer 236 beyond opening 232, third barrier layer 222 is removed resulting in the cross-sectional profile as depicted. The absence of a third barrier layer in the present embodiment enables the placement of a single barrier layer over both a portion of third dielectric 220 and conductive layer 236 without the adjacent placement of barrier layers.

An integrated circuit having a dual damascene interconnection comprised of the various dielectric and barrier layers which facilitates the direct physical coupling of the conductive layer located within the trench and via hole openings with the conductive region of a lower layer has been presented. The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed and desired to be secured by United States Letters Patent is:

1. In an integrated circuit, a dual damascene interconnection comprising:
a. a generally planar substrate including a conductive region and a first dielectric layer located adjacent to said conductive region;
b. a first barrier layer overlying at least a portion of said substrate, said first barrier layer including an aperture therein which aligns with at least a portion of said conductive region of said substrate, said aperture defining a void in said first barrier layer;
c. a second dielectric layer overlying said first barrier layer, said second dielectric layer including a lower trench defining a void in said second dielectric layer, said lower trench encompassing said aperture of said first barrier layer;
d. a second barrier layer overlying said second dielectric layer, said second barrier layer including an aperture therein aligning with said lower trench of said second dielectric layer, said aperture defining a void in said second barrier layer;
e. a third dielectric layer overlying said second barrier layer, said third dielectric layer including a trench defining a void in said third dielectric layer throughout the entire thickness of said third dielectric layer, said trench encompassing said aperture in said second barrier layer; and
f. a second conductive region filled into remaining portions of said trench, said apertures of said first and second barrier layers and said lower trench.

2. The interconnection, as recited in claim 1, wherein said second conductive region is encompassed on said horizontal surfaces by said first and second barrier layers.

3. The interconnection, as recited in claim 1, wherein said first conductive region and said second conductive region are directly in physical and electrical contact to provide a minimum resistance interface without an intervening barrier therebetween.

4. The interconnection, as recited in claim 1, further comprising a third barrier layer about a top surface of said third dielectric.

5. The interconnection, as recited in claim 1, further comprising a fourth barrier layer formed by deposition of barrier material about the surface area of said trench and said lower trench and anisotropically etching said fourth barrier layer to remove horizontal portions of said fourth barrier layer.

6. The interconnection, as recited in claim 5, wherein said fourth barrier layer comprises a metallic barrier.

7. The interconnection, as recited in claim 6, wherein material for said fourth barrier layer is selected from the group consisting of refractory metals and refractory metal compounds including TiN, WN and TaN.

8. The interconnection, as recited in claim 1, wherein said first conductive region and said second conductive region are comprised of copper-based metals.

9. The interconnection, as recited in claim 4, wherein said third barrier layer comprises a dielectric barrier.

10. A dual damascene integrated circuit interconnection comprising:
a. a first conductive region adjacent to a first dielectric;
b. a second dielectric having a lower trench formed therethrough, said via hole overlaying at least a portion of said conductive region;
c. a third dielectric having a trench formed therethrough, said trench overlaying said via hole;
d. a barrier layer formed on vertical walls of said trench and said via hole; and
e. a second conductive region filled into said trench and said via hole having said barrier layer on said vertical walls therein, said second conductive region being in direct physical and electrical contact with said first conductive region.

11. The interconnection, as recited in claim 10, further comprising:
a. a horizontal dielectric barrier layer between said second and third dielectric layers, said horizontal barrier layer for providing a horizontal barrier to said second conductive region when said horizontal walls of said barrier layer formed within said trench and said via hole are anisotropically etched.

12. The interconnection, as recited in claim 10, wherein material for said barrier layer is selected from the group consisting of refractory metals and refractory metal compounds including TiN, WN and TaN.

13. The interconnection, as recited in claim 10, wherein said first conductive region and said second conductive region are comprised of copper-base metals.

14. The interconnection, as recited in claim 10, wherein said barrier layer overlays said third dielectric and is formed on horizontal and vertical walls of said trench and said via hole and on said conductive region in contact with said via hole, said barrier layer being anisotropically etched to remove said barrier layer from horizontal walls of said trench, said via hole and said first conductive region.

15. A method for manufacturing a dual damascene interconnection in an integrated circuit, comprising the steps of:
a. forming a first barrier layer overlaying a first conductive region and an adjacent first dielectric on a substrate;
b. forming a second dielectric layer overlaying said first barrier layer, said second dielectric for insulating said first conductive region and defining a via hole therein;
c. forming a second barrier layer overlaying said second dielectric and patterning in said second barrier layer an aperture through which said via hole will be formed;
d. forming a third dielectric overlaying said second barrier layer, said third dielectric for forming an interconnection trench therein;
e. anisotropically etching said trench and said via hole through said apertures of said third dielectric layer and said second barrier layer, respectively, to said first conductive region;
f. forming a barrier layer overlaying vertical and horizontal surfaces of said trench and via hole and a surface of said first conductive region within said via hole and removing portions of said barrier layer on said horizontal surfaces of said trench, said via hole and said surface of said first conductive region within said via hole and retaining vertical portions of said barrier layer; and
g. filling a remaining portion of said trench and via hole with conductive material to form a second conductive region comprised of a via in said via hole and an interconnection in said trench, said first conductive region being in direct physical contact with said second conductive region.

16. The method for manufacturing, as recited in claim 15, further comprising the step of forming a third barrier layer overlaying said third dielectric and patterning in said third barrier layer an aperture through which said trench will be formed.

17. The method for manufacturing, as recited in claim 15, wherein said barrier layer is a conductive material for providing an electromigration barrier in a horizontal direction to said conductive material forming said second conductive region and said first and second barrier layers providing an electromigration barrier in a vertical direction to said conductive material forming said second conductive region.

18. The method for manufacturing, as recited in claim 17, wherein said conductive material of said barrier layer is selected from the group consisting of refractory metals and refractory metal compounds including TiN, WN and TaN.

19. The method for manufacturing, as recited in claim 17, wherein said first conductive region and said second conductive region are comprised of copper-based metals.
